(19) United States
(12) Patent Application Publication
(10) Pub. No.: US 2026/0081593 A1
(43) Pub. Date: Mar. 19, 2026

(54) SEMICONDUCTOR INTEGRATED CIRCUIT

(71) Applicant: Kioxia Corporation, Tokyo (JP)

(72) Inventors: Koji KOHARA, Yokohama Kanagawa (JP); Naoki WAKITA, Kawasaki Kanagawa (JP); Akikuni SATO, Yokohama Kanagawa (JP)

(73) Assignee: Kioxia Corporation, Tokyo (JP)

(21) Appl. No.: 19/076,203

(22) Filed: Mar. 11, 2025

(30) Foreign Application Priority Data
Sep. 19, 2024 (JP) 2024-162424

(51) Int. Cl. H03K 17/16

(52) U.S. Cl. CPC H03K 17/162; H03K 2217/0036

(57) ABSTRACT

According to one embodiment, in a semiconductor integrated circuit, a switch is connected between a first power supply and a second power supply. The switch turns off when receiving a first level at a control terminal. A first control circuit includes an input node and an output node. The output node is connected to the control terminal of the switch. A second control circuit includes an output node and an input node. The input node is connected to the control terminal of the switch. The semiconductor integrated circuit satisfies at least one of a condition that drive strength to the first level is greater than drive strength to the second level in the first control circuit and another condition that the drive strength to the second level is greater than the drive strength to the first level in the second control circuit.

### CROSS-REFERENCE TO RELATED APPLICATIONS

This application is based upon and claims the benefit of Japanese Patent Application No. 2024-162424, filed on Sep. 19, 2024; the entire contents of which are incorporated herein by reference.

### FIELD

Embodiments described herein relate generally to a semiconductor integrated circuit.

### BACKGROUND

Semiconductor integrated circuits such as power switches can receive power supply, supply the power supply to a circuit of a connection destination, and interrupt the power supply. In the semiconductor integrated circuit, it is desired to appropriately interrupt the power supply to the connection destination.

### BRIEF DESCRIPTION OF THE DRAWINGS

FIG. 1 is a plan view illustrating a configuration of a semiconductor integrated circuit according to a first embodiment;

FIG. 2 is a circuit diagram illustrating a configuration of a semiconductor integrated circuit according to the first embodiment;

FIG. 3 is a circuit diagram illustrating a configuration of a power switch according to the first embodiment;

FIG. 4 is a circuit diagram illustrating a detail configuration of the power switch according to the first embodiment;

FIGS. 5A and 5B are diagrams illustrating threshold voltage distributions of SVT and LVT in the first embodiment;

FIGS. 6A to 6D are waveform diagrams illustrating operations of the power switch in the first embodiment;

FIG. 7 is a circuit diagram illustrating a configuration of a power switch according to a second embodiment;

FIG. 8 is a circuit diagram illustrating a detail configuration of the power switch according to the second embodiment;

FIGS. 9A to 9D are diagrams illustrating leakage current paths in the second embodiment;

FIG. 10 is a circuit diagram illustrating a configuration of a power switch according to a third embodiment;

FIG. 11 is a circuit diagram illustrating a detail configuration of the power switch according to the third embodiment;

FIGS. 12A and 12B are diagrams illustrating adjustment of voltage divider ratio by an assist circuit in the third embodiment; and

FIG. 13 is a circuit diagram illustrating a detail configuration of a power switch according to a fourth embodiment.

### DETAILED DESCRIPTION

In general, according to one embodiment, there is provided a semiconductor integrated circuit including a switch, a first control circuit and a second control circuit. The switch is connected between a first power supply node and a second power supply node that turns off when receiving a first level at a control terminal. The first control circuit has an input node and an output node connected to a control terminal of the switch. The second control circuit has an output node and an input node connected to a control terminal of the switch. The semiconductor integrated circuit satisfies at least one of a condition that drive strength to the first level is greater than drive strength to a second level in the first control circuit and another condition that drive strength to the second level is greater than drive strength to the first level in the second control circuit.

Exemplary embodiments of a semiconductor integrated circuit will be explained below in detail with reference to the accompanying drawings. The present invention is not limited to the following embodiments.

### First Embodiment

The semiconductor integrated circuit according to the first embodiment can receive power supply, supply the power supply to a circuit of a connection destination, or interrupt the power supply, and is designed to properly interrupt the power to the connection destination.

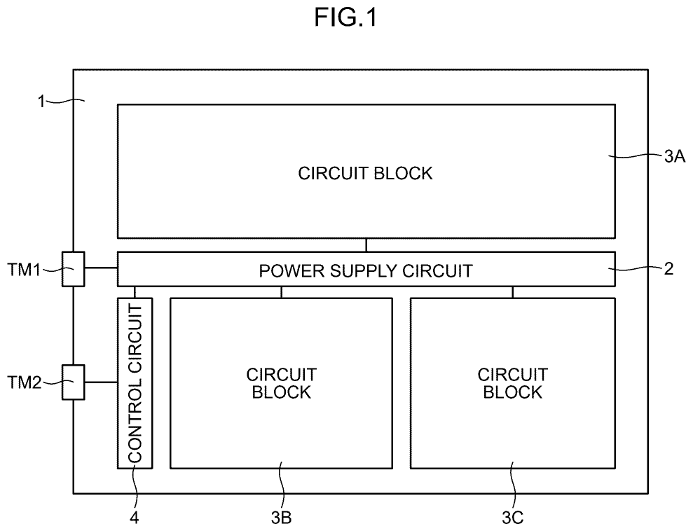

A semiconductor integrated circuit 1 includes, as illustrated in FIG. 1, a power supply terminal TM1, a control terminal TM2, a power supply circuit 2, a plurality of circuit blocks 3A to 3C, and a control circuit 4. FIG. 1 is a plan view illustrating a configuration of the semiconductor integrated circuit.

The power supply circuit 2 is connected to the power supply terminal TM1, the control circuit 4, and the plurality of circuit blocks 3A to 3C. The control circuit 4 is connected to the control terminal TM2 and the power supply circuit 2. The plurality of circuit blocks 3A to 3C is connected to the power supply circuit 2, respectively.

The control circuit 4 receives a control signal CTR from an external device (for example, a controller) via the control terminal TM2. The control circuit 4 generates control signals CNTA, CNTB, and CNTC depending on the control signal CTR, and supplies the control signals to the power supply circuit 2.

The power supply circuit 2 receives a power supply voltage TVDD from an external device (for example, a controller) via the power supply terminal TM1. The power supply circuit 2 generates the power voltages VDD_A, VDD_B, and VDD_C using the power supply voltage TVDD. The power supply circuit 2 supplies and interrupts the power supply voltages VDD_A, VDD_B, and VDD_C, depending on the control signals CNTA, CNTB, and CNTC, to the circuit blocks 3A, 3B, and 3C, respectively.

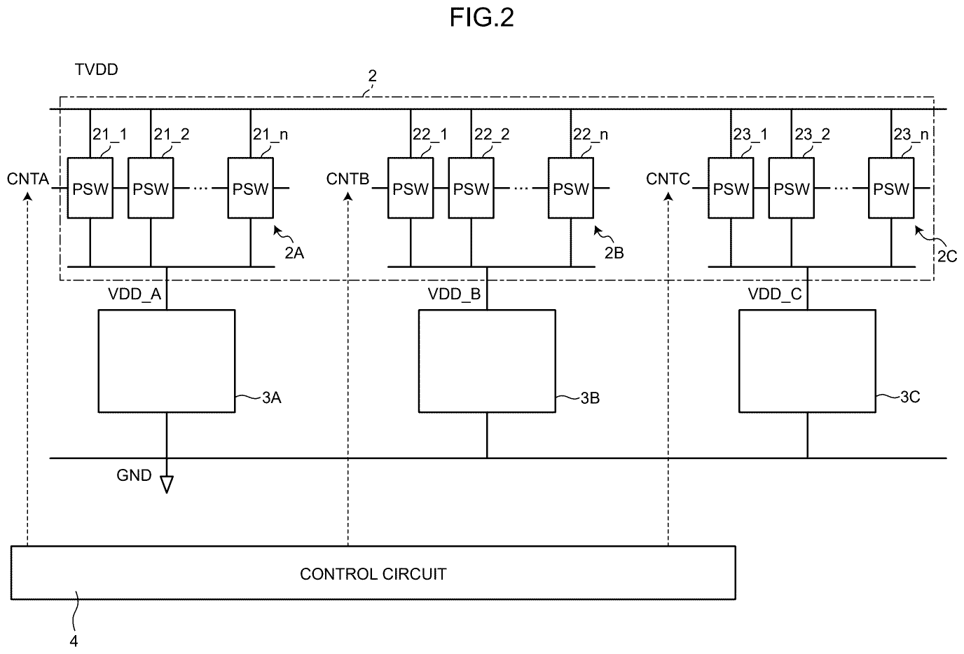

The power supply circuit 2 is configured to, as illustrated in FIG. 2, perform power supply and power interruption to the plurality of circuit blocks 3A, 3B, and 3C. FIG. 2 is a circuit diagram illustrating a configuration of the power supply circuit 2.

The power supply circuit 2 includes a plurality of power switch groups 2A, 2B, and 2C. The plurality of power switch groups 2A, 2B, and 2C corresponds to the plurality of circuit blocks 3A, 3B, and 3C, and corresponds to a plurality of control lines CNTA, CNTB, and CNTC. Each of the power switch groups 2 is connected between the power supply terminal TM1 and the circuit block 3.

The power switch group 2A is connected to the power supply terminal TM1 via a global power supply line TVDD, connected to the circuit block 3A via a local power supply line VDD_A, and connected to the control circuit 4 via the control line CNTA.

Now assumed that n is any integer greater than or equal to 2. The power switch group 2A is configured to perform power supply and power interruption to the circuit block 3A. The power switch group 2A includes n power switches (PSW) 21_1 to 21_n. The n PSW 21_1 to 21_n are connected in parallel between the global power supply line TVDD and the local power supply line VDD_A, and connected in series to the control line CNTA.

In each of the PSW 21, an input node IN is connected to the control line CNTA or the PSW 21 in the preceding stage, an output node OUT is connected to the PSW 21 in the next stage, a power supply node TVDD is connected to the global power supply line TVDD, and a power supply node VDD is connected to the corresponding circuit block 3A via the local power supply line VDD_A.

In the n PSW 21_1 to 21_n, the control signal CNTA is transmitted serially. Each of the PSW 21 supplies and interrupts the power supply to the circuit block 3A depending on the control signal CNTA.

The PSW group 2B is connected to the power supply terminal TM1 via the global power supply line TVDD, connected to the circuit block 3B via the local power supply line VDD_B, and connected to the control circuit 4 via the control line CNTB.

The PSW group 2B is configured to supply and interrupt power supply to the circuit block 3B. The PSW group 2B includes n PSW 22_1 to 22_n. The n PSW 22_1 to 22_n are connected in parallel between the global power supply line TVDD and the local power supply line VDD_B, and connected in series to the control line CNTB.

In each of the PSW 22, the input node IN is connected to the control line CNTB or the PSW 22 in the preceding stage, the output node OUT is connected to the PSW 22 in the next stage, the power supply node TVDD is connected to the global power supply line TVDD, and the power supply node VDD is connected to the circuit block 3B via the local power supply line VDD_B.

In the n PSW 22_1 to 22_n, the control signal CNTB is transmitted serially. Each of the PSW 22 supplies and interrupts power supply to the circuit block 3B depending on the control signal CNTB.

The PSW group 2C is connected to the power supply terminal TM1 via the global power supply line TVDD, connected to the circuit block 3C via the local power supply line VDD_C, and connected to the control circuit 4 via the control line CNTC.

The PSW group 2C is configured to supply and interrupt power supply to the circuit block 3C. The PSW group 2C includes n PSW 23_1 to 23_n. The n PSW 23_1 to 23_n are connected in parallel between the global power supply line TVDD and the local power supply line VDD_C, and connected in series to the control line CNTC.

In each of the PSW 23, the input node IN is connected to the control line CNTC or the PSW 23 in the preceding stage, the output node OUT is connected to the PSW 23 in the next stage, the power supply node TVDD is connected to the global power supply line TVDD, and the power supply node VDD is connected to the circuit block 3C via the local power supply line VDD_C.

In the n PSW 23_1 to 23_n, the control signal CNTC is transmitted serially. Each of the PSW 23 supplies and interrupts power supply to the circuit block 3C depending on the control signal CNTC.

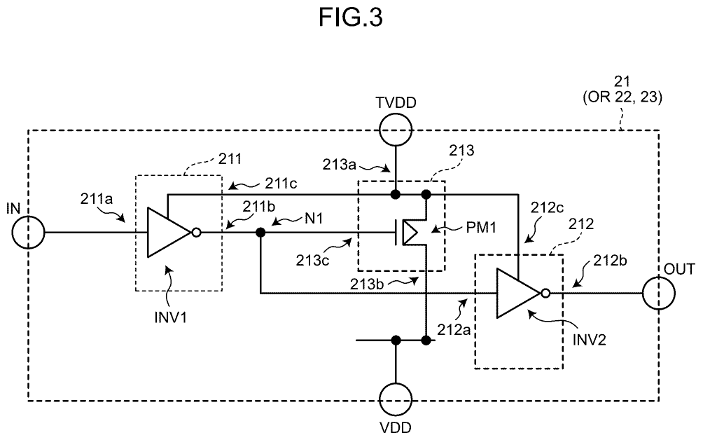

Next, the configuration of each of the PSW 21 will be explained with reference to FIG. 3. FIG. 3 is a circuit diagram illustrating the configuration of the PSW 21. In FIG. 3, the configuration of PSW 21 is illustrated as an example, but the configurations of PSW 22 and PSW 23 are similar to that of PSW 21.

The PSW 21 includes a switch 213, a control circuit 211, and a control circuit 212.

The switch 213 is connected between the power supply node TVDD and the power supply node VDD. In the switch 213, one end 213a is connected to the power supply node TVDD, an other end 213b is connected to the power supply node VDD, and a control terminal 213c is connected to a node N1. The switch 213 turns off when receiving a H level at the control terminal 213c.

The switch 213 may include a transistor PM1. The transistor PM1 is, for example, a PMOS transistor. In the transistor PM1, the source is connected to the power supply node TVDD, the drain is connected to the power supply node VDD, and the gate is connected to the node N1. The transistor PM1 turns off when receiving the H level at the gate.

The control circuit 211 is connected between the input node IN and the node N1 of the PSW 21. In the control circuit 211, the input node 211a is connected to the input node IN, the output node 211b is connected to the control terminal 213c of the switch 213 via the node N1, and the power supply node 211c is connected to the power supply node TVDD.

The control circuit 211 may include an inverter INV1. In the inverter INV1, an input node is connected to the input node IN and an output node is connected to the node N1.

The control circuit 212 is connected between the node N1 and the output node OUT of the PSW 21. In the control circuit 212, the input node 211a is connected to the control terminal 213c of the switch 213 via the node N1, the output node 212b is connected to the output node OUT, and the power supply node 212c is connected to the power supply node TVDD.

The control circuit 212 may include an inverter INV2. In the inverter INV2, an input node is connected to the node N1 and an output node is connected to the output node OUT.

The PSW 21 is configured such that drive strength to the H level is larger than drive strength to the L level in the control circuit 211 and drive strength to the L level is greater than drive strength to the H level in the control circuit 212.

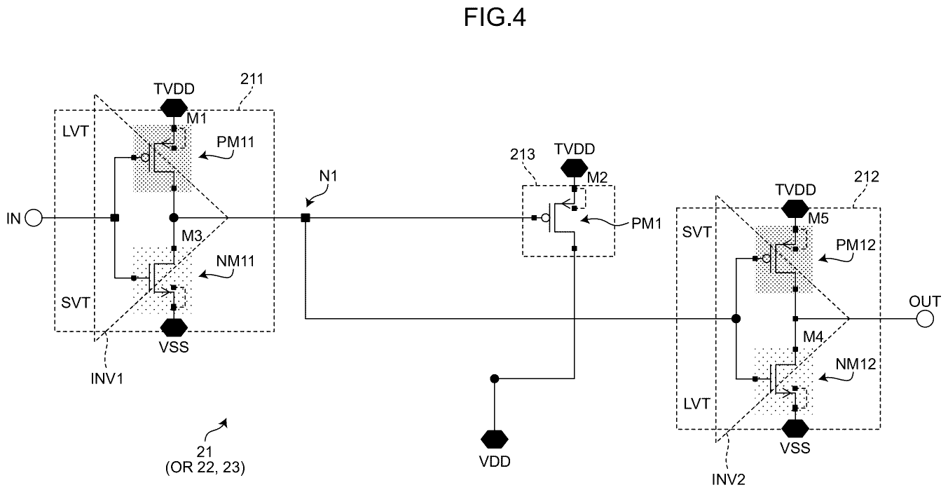

The PSW 21 may be configured as illustrated in FIG. 4. FIG. 4 is a circuit diagram illustrating a detail configuration of the PSW 21.

The inverter INV1 of the control circuit 211 includes a transistor PM11 and a transistor NM11. The transistor PM11 and the transistor NM11 are inverter-connected. The transistor PM11 may be a PMOS transistor. The transistor NM11 may be an NMOS transistor. In the transistor PM11 and the transistor NM11, gates are commonly connected to be connected to the input node IN, and drains are commonly connected to be connected to the node N1. In the transistor PM11, the source is connected to the power supply node TVDD. In the transistor NM11, the source is connected to a ground node VSS.

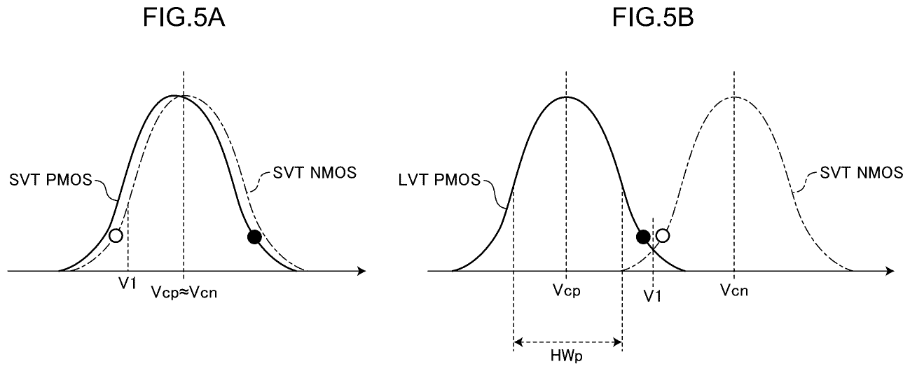

The threshold voltage of the transistor PM11 is lower than the threshold voltage of the transistor NM11. For example, the difference between the center voltage in the threshold voltage distribution of the transistor PM11 and the center voltage for the threshold voltage of the transistor NM11 is more than half the width of the threshold voltage distribution of the transistor PM11 (see FIG. 5B). This allows the drive strength to the H level to be greater than the drive strength to the L level in the control circuit 211.

The transistor PM11 may include a low threshold voltage transistor (LVT). The transistor NM11 may include a standard threshold voltage transistor (SVT).

Since the inverter INV1 includes the LVT transistor PM11 and the SVT transistor NM11, the output tends to be at the H level when the input is at the L level. The threshold voltage distribution of LVT PMOS is depicted by a solid line in FIG. 5B, and the threshold voltage distribution of SVT NMOS is depicted by a dash-dotted line in FIG. 5B. FIGS. 5A, 5B are diagrams illustrating the threshold voltage distributions of SVT and LVT. In FIGS. 5A, 5B, the vertical axis indicates the number of transistors and the horizontal axis indicates the voltage.

The threshold voltage distribution of LVT PMOS is shifted to the lower voltage side than the threshold voltage distribution of SVT NMOS. The center voltage Vcp of the threshold voltage distribution of LVT PMOS is lower than the center voltage Vcn of the threshold voltage distribution of SVT NMOS. The difference between the center voltage Vcp and the center voltage Ven is more than half the width HWp of the threshold voltage distribution of LVT PMOS.

As illustrated in FIG. 5B, even if the threshold voltage of the LVT PMOS is as high as the black dot and the threshold voltage of the SVT NMOS is as low as the white dot due to variations, when the L level (e.g., V1) is supplied to the input node of the inverter, the NMOS is turned off, the PMOS is turned on, and the H level may be output from the output node of the inverter.

The inverter INV2 of the control circuit 212 includes a transistor PM12 and a transistor NM12. The transistor PM12 and the transistor NM12 are inverter-connected. The transistor PM12 may be a PMOS transistor. The transistor NM12 may be an NMOS transistor. In the transistor PM12 and the transistor NM12, gates are commonly connected to be connected to the node N1, and drains are commonly connected to be connected to the output node OUT. In the transistor PM12, the source is connected to the power supply node TVDD. In the transistor NM12, the source is connected to the ground node VSS.

The threshold voltage of the transistor NM12 is lower than the threshold voltage of the transistor PM12. For example, the difference between the center voltage in the threshold voltage distribution of the transistor NM12 and the center voltage for the threshold voltage of the transistor PM12 is more than half the width of the threshold voltage distribution of the transistor NM12. This allows the drive strength to the L level to be greater than the drive strength to the H level in the control circuit 212.

The transistor NM12 may include a low threshold voltage transistor (LVT). The transistor PM12 may include a standard threshold voltage transistor (SVT).

Since the inverter INV2 includes the LVT transistor NM12 and the SVT transistor PM12, the output tends to be at the L level when the input is at the H level.

The threshold voltage distribution of LVT NMOS is shifted to the lower voltage side than the threshold voltage distribution of SVT PMOS. The center voltage of the threshold voltage distribution of LVT NMOS is lower than the center voltage of the threshold voltage distribution of SVT PMOS. The difference between the center voltage in the threshold voltage distribution of the LVT NMOS and the center voltage of the threshold voltage distribution of the SVT PMOS is more than half the width of the threshold voltage distribution of LVT NMOS.

Even if the threshold voltage of the LVT NMOS is higher and the threshold voltage of the SVT PMOS is lower due to variations, when the H level is supplied to the input node of the inverter, the PMOS is turned off, the NMOS is turned on, and the L level may be output from the output node of the inverter.

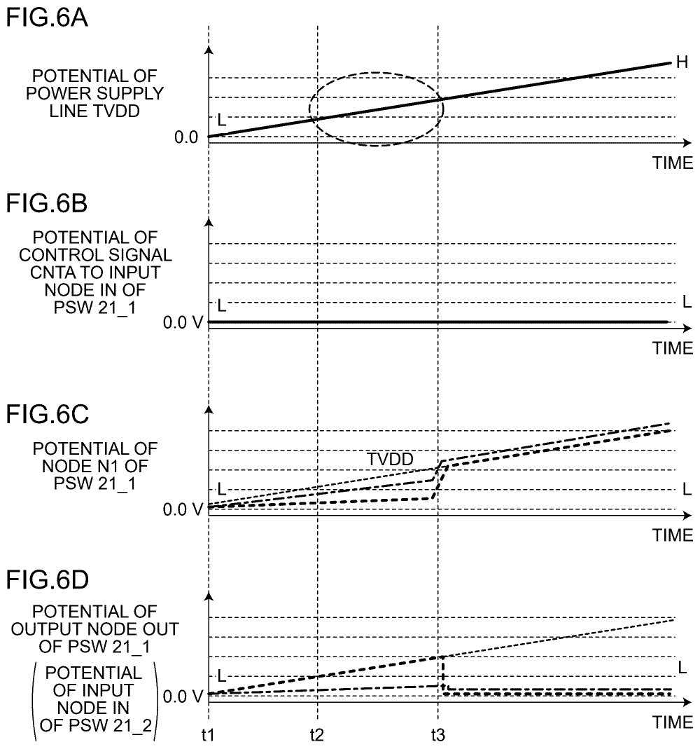

As illustrated in FIG. 6B, for example, it is assumed that in a state where the potential of the control signal CNTA supplied to the input node IN of the PSW 21_1 on the first stage remains at the L level, the potential of the power supply line TVDD starts increasing from the L level at timing t1, as illustrated in FIG. 6A. FIGS. 6A to 6D are waveform diagrams illustrating operations of the PSW 21.

At this time, the transistor PM1 of the switch 213 is turned off.

Immediately after the timing t1, in the inverter INV1 of the PSW 21_1, although the gate-source voltage is relatively small, the transistor PM11 is turned on because it includes an LVT. This allows the potential of the node N1 to start following at the H level close to the potential of the power supply line TVDD as indicated by a dash-dotted line in FIG. 6C. As a result, the transistor PM1 of the switch 213 remains in an off state.

Correspondingly, in the inverter INV2 of the PSW 21_1, although the gate-source voltage is relatively small, the transistor NM12 is turned on because it includes an LVT. This allows the potentials of the output node OUT of the PSW 21_1 and the input node IN of the PSW 21_2 in the next stage to remain at around the L level as indicated by a dash-dotted line in FIG. 6D.

At the timing t2, in the inverter INV1 of the PSW 21_1, although the gate-source voltage is relatively small, the transistor PM11 can remain turned on because it includes an LVT. This allows the potential of the node N1 to be able to continue following at the H level close to the potential of the power supply line TVDD as indicated by a dash-dotted line in FIG. 6C. As a result, the transistor PM1 of the switch 213 remains in an off state.

Correspondingly, in the inverter INV2 of the PSW 21_1, although the gate-source voltage is relatively small, the transistor NM12 can remain turned on because it includes an LVT. This allows the potentials of the output node OUT of the PSW 21_1 and the input node IN of the PSW 21_2 in the next stage to remain at around the L level as indicated in FIG. 6D.

At the timing t3, in the inverter INV1 of the PSW 21_1, the transistor PM11 remains turned on because the gate-source voltage is relatively large. This allows the potential of the node N1 to be able to continue following at the H level close to the potential of the power supply line TVDD as indicated by a dash-dotted line in FIG. 6C. As a result, the transistor PM1 of the switch 213 remains in an off state.

Correspondingly, in the inverter INV2 of the PSW 21_1, the transistor NM12 remains turned on because the gate-source voltage is relatively large. This allows the potentials of the output node OUT of the PSW 21_1 and the input node IN of the PSW 21_2 in the next stage to remain at the L level as indicated in FIG. 6D.

After the timing t3, in the inverter INV1 of the PSW 21_1, the transistor PM11 stably turns on, and the potential of the node N1 stably follows at the H level close to the potential of the power supply line TVDD as indicated by a dash-dotted line in FIG. 6C. As a result, the transistor PM1 of the switch 213 stably remains in an off state.

Correspondingly, in the inverter INV2 of the PSW 21_1, the transistor NM12 stably turns on, and the potentials of the output node OUT of the PSW 21_1 and the input node IN of the PSW 21_2 in the next stage stably remain at the L level as indicated in FIG. 6D.

As described above, according to the first embodiment, in the semiconductor integrated circuit 1, the PSW 21 is configured such that the drive strength to the H level is greater than the drive strength to the L level in the control circuit 211. This allows the leakage at the time of power-on to be suppressed in the switch 213 to be turned off, thereby being able to reduce power consumption in the standby state. Therefore, it is possible to appropriately interrupt the power supply to the connection destination of the PSW 21.

In addition, according to the first embodiment, in the semiconductor integrated circuit 1, the PSW 21 is configured such that the drive strength to the L level is greater than the drive strength to the H level in the control circuit 212. As a result, the signal to be transmitted to the PSW 21 in the next stage can be easily suppressed to the L level, and the leakage due to an influence of the preceding stage at the time of power-on can be suppressed in the switch 213 to be turned off, thereby being able to reduce power consumption in the standby state. Therefore, it is also possible to appropriately interrupt the power supply to the connection destination of the PSW 21 in the next stage.

For example, if the inverter includes an SVT PMOS and an SVT NMOS, an output may be at the L level when an input is at the L level. The threshold voltage distribution of SVT PMOS is depicted by a solid line in FIG. 5A, and the threshold voltage distribution of SVT NMOS is depicted by a dash-dotted line in FIG. 5A. FIGS. 5A, 5B are diagrams illustrating the threshold voltage distributions of SVT and LVT. In FIG. 5A, the vertical axis indicates the number of transistors and the horizontal axis indicates the voltage. The threshold voltage distribution of SVT PMOS and the threshold voltage distribution of SVT NMOS almost overlap. The center voltage Vcp of the threshold voltage distribution of SVT PMOS and the center voltage Vcn of the threshold voltage distribution of SVT NMOS are almost the same.

As illustrated in FIG. 5A, if the threshold voltage of the SVT PMOS is as high as the black dot and the threshold voltage of the SVT NMOS is as low as the white dot due to variations, when the L level (e.g., V1) is supplied to the input node of the inverter, the NMOS is turned on, the PMOS is turned off, and the L level may be output from the output node of the inverter.

For example, for the PSW 21 illustrated in FIG. 4, consideration will be given to the PSW 21s having a configuration that has been changed so that an inverter INV1s of the control circuit 211s includes an SVT transistor PM11s and an SVT transistor NM11, an inverter INV2s of the control circuit 212s includes an SVT transistor PM12 and an SVT transistor NM12s.

As illustrated in FIG. 6B, for example, it is assumed that in a state where the potential of the control signal CNTS supplied to the input node IN of the PSW 21s_1 on the first stage remains at the L level, the potential of the power supply line TVDD starts increasing from the L level at timing t1, as illustrated in FIG. 6A.

At this time, the transistor PM1 of the switch 213 is turned off.

Immediately after the timing t1, in the inverter INV1s of the PSW 21s_1, the transistor PM11s is turned off because the gate-source voltage is relatively small and the transistor includes an SVT. This allows the potential of the node N1 to start dissociating from the potential of the power supply line TVDD to the L level as indicated by a dotted line in FIG. 6C. As a result, the transistor PM1 of the switch 213 starts to be in a half-on state.

Correspondingly, in the inverter INV2s of the PSW 21s_1, the transistor NM12s is turned off because the gate-source voltage is relatively small and the transistor includes an SVT. This allows the potentials of the output node OUT of the PSW 21s_1 and the input node IN of the PSW 21s_2 in the next stage to start following at the H level close to the potential of the power supply line TVDD as indicated by a dotted line in FIG. 6D.

At the timing t2, in the inverter INV1s of the PSW 21s_1, the transistor PM11s is turned off because the gate-source voltage is relatively small and the transistor includes an SVT. This allows the potential of the node N1 to continue dissociating from the potential of the power supply line TVDD to the L level as indicated by a dotted line in FIG. 6C. As a result, the transistor PM1 of the switch 213 turns to be in a further strong half-on state.

Correspondingly, in the inverter INV2s of the PSW 21s_1, the transistor NM12s continues to be turned off because the gate-source voltage is relatively small and the transistor includes an SVT. This allows the potentials of the output node OUT of the PSW 21s_1 and the input node IN of the PSW 21s_2 in the next stage to continue further following at the H level close to the potential of the power supply line TVDD as indicated by a dotted line in FIG. 6D.

At the timing t3, in the inverter INV1s of the PSW 21s_1, the transistor PM11s turns on because the gate-source voltage is relatively large. This allows the potential of the node N1 to start following at the H level close to the potential of the power supply line TVDD as indicated by a dotted line in FIG. 6C. As a result, the transistor PM1 of the switch 213 transitions from a half-on state to an off state, and starts to remain in the off state.

Correspondingly, in the inverter INV2s of the PSW 21s_1, the transistor NM12s turns on because the gate-source voltage is relatively large. This allows the potentials of the output node OUT of the PSW 21s_1 and the input node IN of the PSW 21_2 in the next stage to be at the L level as indicated by a dotted line in FIG. 6D, and to start to remain at the L level.

In other words, in the PSW 21s, since the transistor PM1 of the switch 213 is in the half-on state at the timing t1 to t3, due to the leakage of the transistor PM1, the power consumption in the standby state is likely to increase.

On the other hand, the PSW 21 according to the present embodiment is configured such that the inverter INV1 of the control circuit 211 includes the LVT transistor PM11 and the SVT transistor NM11, and the inverter INV1 of the control circuit 212 includes the SVT transistor PM12 and the LVT transistor NM12. This allows the leakage at the time of power-on to be suppressed in the switch 213 to be turned off, thereby being able to reduce power consumption in the standby state.

It should be noted that the PSW 21′ may be configured such that the drive strength to the H level is greater than the drive strength to the L level in the control circuit 211 and the drive strength to the L level and the drive strength to the H level in the control circuit 212s are substantially equal. In the PSW 21′, the inverter INV2 illustrated in FIG. 4 is changed so as to include the SVT transistor PM12 and the SVT transistor NM12s, and the inverter INV2s of the control circuit 212s may be configured. In this case, since the drive strength to the H level is larger than the drive strength to the L level in the control circuit 211 of the PSW 21′, the node N1 can be easily set to the H level at the time of power-on. This allows the leakage at the time of power-on to be suppressed in the switch 213 to be turned off.

Alternatively, the PSW 21″ may be configured such that the drive strength to the H level is substantially equal to drive strength to the L level in the control circuit 211s and the drive strength to the L level is greater than the drive strength to the H level in the control circuit 212. In the PSW 21″, the inverter INV1 illustrated in FIG. 4 is changed so as to include the SVT transistor PM11s and the SVT transistor NM11, and the inverter INV1s of the control circuit 211s may be configured. In this case, since the drive strength to the L level is greater than the drive strength to the H level in the control circuit 212 of the PSW 21″, the output node OUT can be easily set to the L level at the time of power-on. This allows the leakage due to the influence from the preceding stage at the time of power-on to be suppressed in the switch 213 to be turned off.

### Second Embodiment

Next, a semiconductor integrated circuit 1i according to the second embodiment will be explained. In the following, the parts that differ from the first embodiment will be mainly explained.

While the first embodiment has been presented as an example of a configuration for reducing the leakage of the switch 213 by adjusting the drive strength of the control circuit in the PSW, the second embodiment is presented as an example of a configuration for reducing the leakage of the switch 213 by adding an assist circuit in the PSW.

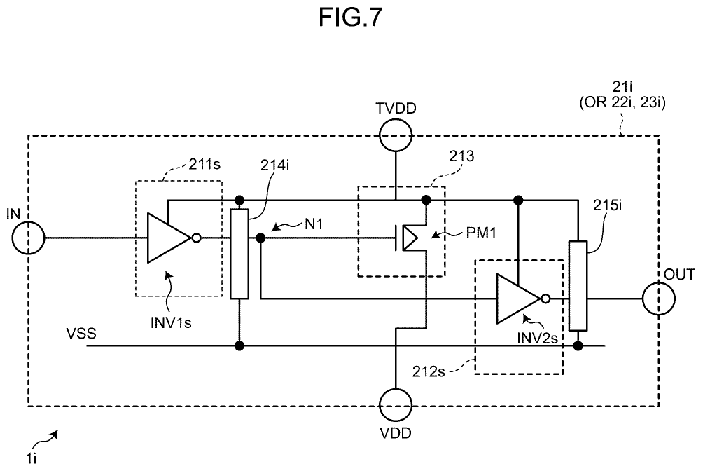

In the semiconductor integrated circuit 1i, a PSW 21i (or 22i, 23i) may be configured as illustrated in FIG. 7. FIG. 7 is a circuit diagram illustrating a configuration of the PSW 21i according to the second embodiment. In FIG. 7, the configuration of PSW 21i is illustrated as an example, and the configurations of PSW 22i and PSW 23i are similar to that of PSW 21i.

The PSW 21i includes, instead of the control circuit 211, the control circuit 212 (see FIG. 3), a control circuit 211s, a control circuit 212s, and further includes an assist circuit 214i and an assist circuit 215i.

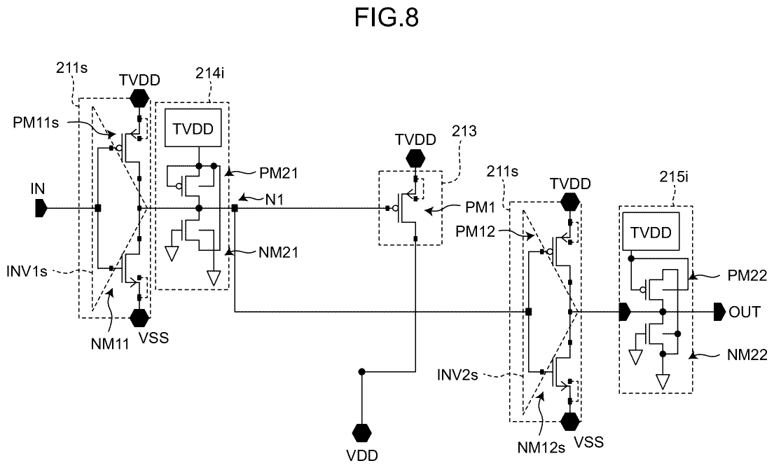

In the control circuit 211s, the drive strength to the H level and the drive strength to the L level may be equal. The inverter INV1s of the control circuit 211s may include, as illustrated in FIG. 8, an SVT transistor PM11s and an SVT transistor NM11. FIG. 8 is a circuit diagram illustrating a detail configuration of a PSW 21i according to the second embodiment.

In the control circuit 212s illustrated in FIG. 7, the drive strength to the H level and the drive strength to the L level may be substantially equal. The inverter INV2s of the control circuit 212s may include, as illustrated in FIG. 8, the SVT transistor PM11s and the SVT transistor NM11.

The assist circuit 214i illustrated in FIG. 7 is connected between the control circuit 211s and the switch 213. The assist circuit 214i may be connected between the control circuit 211s and the node N1. The assist circuit 214i is connected between the power supply potential TVDD and the ground potential VSS at a position between the control circuit 211s and the switch 213. The assist circuit 214i may be connected between the power supply potential TVDD and the ground potential VSS at a position between the control circuit 211s and the node N1. This allows the assist circuit 214i to assist such that the H level appears at the output node of the control circuit 211s when the L level is input to the input node of the control circuit 211s in a state where the switch 213 remains turned off.

The assist circuit 214i includes, as illustrated in FIG. 8, at least one of the transistor PM21 and the transistor NM21. In FIG. 8, the assist circuit 214i that includes the transistor PM21 and the transistor NM21 is illustrated as an example. The transistor PM21 and the transistor NM21 are each reverse polarity connected. The transistor PM21 may be a PMOS transistor. The transistor NM21 may be an NMOS transistor.

In the transistor PM21 and the transistor NM21, drains are commonly connected to be connected to the node N1. In the transistor PM21, the gate, the source and the back gate are each connected to the power supply node TVDD. In the transistor NM21, the source is connected to the power supply node TVDD, and the gate and the back gate are each connected to the ground node VSS.

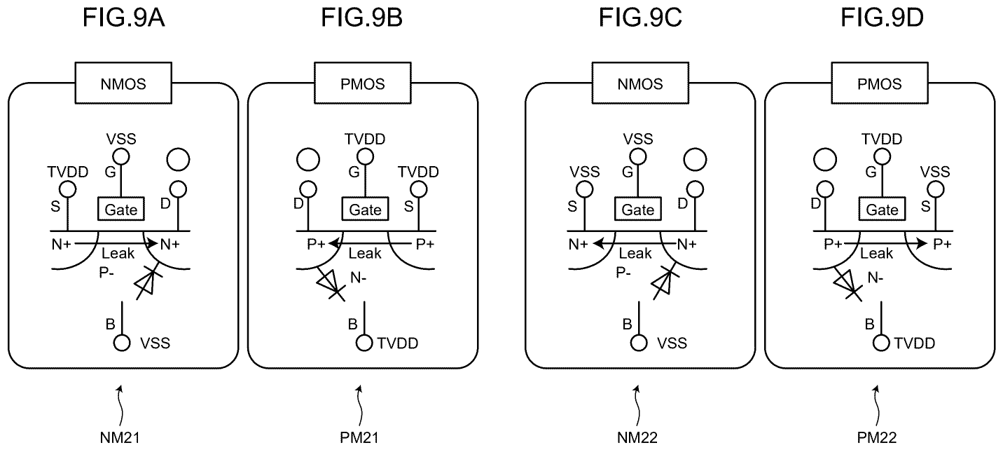

In the transistor PM21, as illustrated in FIG. 9B, since the gate is connected to the power supply node TVDD, the off state is kept, however, since the source is connected to the power supply node TVDD and the drain is in a floating state, a leakage current may flow from the source to the drain. This allows the drain to be charged, albeit little by little, to raise the potential to the H level side.

In the transistor NM21, as illustrated in FIG. 9A, since the gate is connected to the ground node VSS, the off state is kept, however, since the source is connected to the power supply node TVDD and the drain is in a floating state, a leakage current may flow from the source to the drain. This allows the drain to be charged to raise the potential to the H level side little by little.

This can assist appearance of the H level at the output node of the control circuit 211s when the L level is input to the input node of the control circuit 211s in a state where the switch 213 remains turned off.

The assist circuit 215i illustrated in FIG. 7 is connected between the control circuit 212s and the output node OUT. The assist circuit 215i is connected between the power supply potential TVDD and the ground potential VSS at a position between the control circuit 212s and the output node OUT. This allows the assist circuit 215i to assist such that the L level appears at the output node of the control circuit 212s when the H level is input to the input node of the control circuit 212s in a state where the switch 213 remains turned off.

The assist circuit 215i includes, as illustrated in FIG. 8, at least one of a transistor PM22 and a transistor NM22. In FIG. 8, the assist circuit 215i that includes the transistor PM22 and the transistor NM22 is illustrated as an example. The transistor PM22 and the transistor NM22 are each reverse polarity connected. The transistor PM22 may be a PMOS transistor. The transistor NM22 may be an NMOS transistor.

In the transistor PM22 and the transistor NM22, drains are commonly connected to be connected to the output node OUT. In the transistor PM22, the source is connected to the ground node VSS, and the gate and the back gate are each connected to the power supply node TVDD. In the transistor NM22, the source, the gate and the back gate are each connected to the ground node VSS.

In the transistor PM22, as illustrated in FIG. 9D, since the gate is connected to the power supply node TVDD, the off state is kept, however, since the source is connected to the ground node VSS and the drain is in a floating state, a leakage current may flow from the drain to the source. This discharges the charge from the drain, albeit little by little, to pull the potential to the L level side.

In the transistor NM22, as illustrated in FIG. 9C, since the gate is connected to the ground node VSS, the off state is kept, however, since the source is connected to the ground node VSS and the drain is in a floating state, a leakage current may flow from the drain to the source. This discharges the charge from the drain, albeit little by little, to pull the potential to the L level side.

This can assist appearance of the L level at the output node of the control circuit 212s when the H level is input to the input node of the control circuit 212s in a state where the switch 213 remains turned off.

As described above, according to the second embodiment, in the PSW 21i of the semiconductor integrated circuit 1i, the assist circuit 214i may assist such that the H level appears at the output node of the control circuit 211s when the L level is input to the input node of the control circuit 211s in a state where the switch 213 remains turned off. This allows the leakage at the time of power-on to be suppressed in the switch 213 to be turned off, thereby being able to reduce power consumption in the standby state. Therefore, it is possible to appropriately interrupt the power supply to the connection destination of the PSW 21i.

In addition, according to the second embodiment, in the PSW 21i of the semiconductor integrated circuit 1i, the assist circuit 215i may assist such that the L level appears at the output node of the control circuit 212s when the H level is input to the input node of the control circuit 212s in a state where the switch 213 remains turned off. As a result, the signal to be transmitted to the PSW 21i in the next stage can be easily suppressed to the L level, and the leakage due to an influence of the preceding stage at the time of power-on can be suppressed in the switch 213 to be turned off, thereby being able to reduce power consumption in the standby state. Therefore, it is also possible to appropriately interrupt the power supply to the connection destination of the PSW 21i in the next stage.

Note that the PSW 21i′ may be configured such that the assist circuit 214i is omitted. In this case, in the PSW 21i′, the assist circuit 215i assists such that the L level appears at the output node of the control circuit 212s when the H level is input to the input node of the control circuit 212s in a state where the switch 213 remains turned off. As a result, the signal to be transmitted to the PSW 21i in the next stage can be easily suppressed to the L level, and the leakage due to an influence of the preceding stage at the time of power-on can be suppressed in the switch 213 to be turned off.

Alternatively, the PSW 21i″ may be configured such that the assist circuit 215i is omitted. In this case, in the PSW 21i″, the assist circuit 214i assists such that the H level appears at the output node of the control circuit 211s when the L level is input to the input node of the control circuit 211s in a state where the switch 213 remains turned off. This allows the leakage at the time of power-on to be suppressed in the switch 213 to be turned off.

### Third Embodiment

Next, a semiconductor integrated circuit 1j according to the third embodiment will be explained. In the following, the parts that differ from the first embodiment and the second embodiment will be mainly explained.

While the second embodiment has been presented as an example of the assist circuit using the leakage, the third embodiment will be presented as an example of an assist circuit using the capacity.

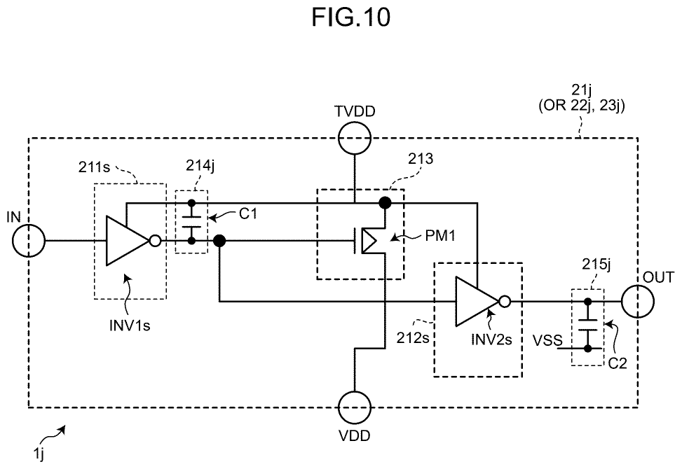

In the semiconductor integrated circuit 1j, a PSW 21j (or 22j, 23j) may be configured as illustrated in FIG. 10. FIG. 10 is a circuit diagram illustrating a configuration of the PSW 21j according to the third embodiment. In FIG. 10, the configuration of PSW 21j is illustrated as an example, and the configurations of PSW 22j and PSW 23j are similar to that of PSW 21j.

The PSW 21j includes an assist circuit 214j and an assist circuit 215j instead of an assist circuit 214i and an assist circuit 215i (see FIG. 7).

The assist circuit 214j illustrated in FIG. 10 is connected between the control circuit 211s and the switch 213. The assist circuit 214j may be connected between the control circuit 211s and the node N1. The assist circuit 214j is connected between the power supply potential TVDD and the node N1 at the position between the control circuit 211s and the switch 213. The assist circuit 214j may be connected between the power supply potential TVDD and the node N1 at the position between the control circuit 211s and the node N1. This allows the assist circuit 214j to assist such that the H level appears at the output node of the control circuit 211s when the L level is input to the input node of the control circuit 211s in a state where the switch 213 remains turned off.

The assist circuit 214j includes a capacitive element C1. The capacitive element C1 includes one end connected to the control terminal of the switch 213 and the other end connected to the power supply node TVDD.

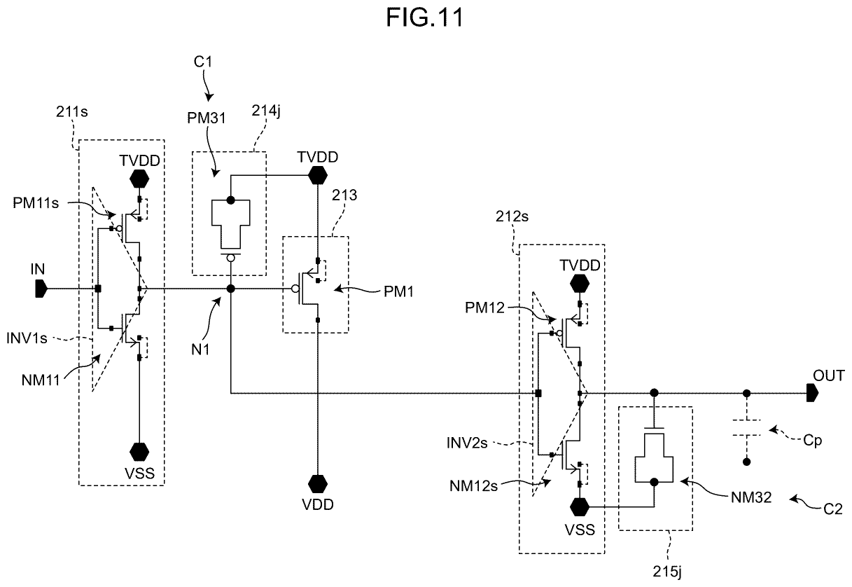

The assist circuit 214j includes, as illustrated in FIG. 11, the transistor PM31. The transistor PM31 is capacitively connected. The transistor PM31 may be a PMOS transistor.

In the transistor PM31, the source and the drain are commonly connected to the power supply node TVDD, and the gate is connected to the node N1. This allows the transistor PM31 to function as the capacitive element C1.

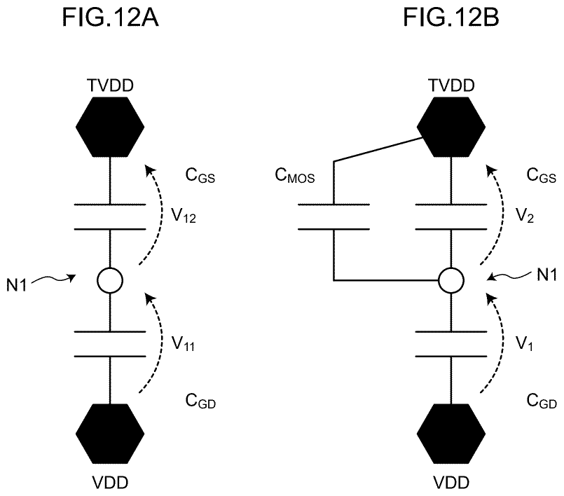

For example, it is assumed that both the gate-drain capacitance C_{GD} of the transistor PM1 and the gate-source capacitance C_{GS} of the transistor PM1 are C and equal. If the assist circuit 214j is omitted, the vicinity of the node N1 is configured, as illustrated in FIG. 12A, such that the capacitance C_{GD}, the node N1, and the capacitance C_{GS} are connected in series between the power supply node TVDD and the power supply node VDD.

The voltage divider ratio between the voltage V11 between the power supply node VDD and the node N1 and the voltage V12 between the node N1 and the power supply node TVDD is V11:V12=1/C:1/C=1:1. At the time of power-on, the power supply node VDD is almost at the ground potential (≈0 V), so the potential of node N1 is about TVDD×1/2.

On the other hand, it is assumed that the gate capacitance of the transistor PM31 is C_{MOS} and the capacitance C_{MOS} is equal to C. If the assist circuit 214j is provided, the vicinity of the node N1 is configured, as illustrated in FIG. 12B, such that the capacitance C_{MOS} and the capacitance C_{GD} are connected in parallel between the power supply node TVDD and the node N1, and the capacitance C_{GD} is connected between the node N1 and the power supply node VDD.

The voltage divider ratio between the voltage V1 between the power supply node VDD and the node N1 and the voltage V2 between the node N1 and the power supply node TVDD is V1:V2=(C+C):1/C=1:2. At the time of power-on, the power supply node VDD is almost at the ground potential (≈0 V), so the potential of node N1 is about TVDD×2/3.

In other words, by providing the assist circuit 214j, the top and bottom of the voltage divider ratio of the node N1 can be adjusted so that the potential of the node N1 is higher at the time of power-on.

This can assist appearance of the H level at the output node of the control circuit 211s when the L level is input to the input node of the control circuit 211s in a state where the switch 213 remains turned off.

The assist circuit 215j illustrated in FIG. 10 is connected between the control circuit 212s and the output node OUT. The assist circuit 215j is connected between the output node OUT and the ground potential VSS at the position between the control circuit 212s and the output node OUT. This allows the assist circuit 215j to assist such that the L level appears at the output node of the control circuit 212s when the H level is input to the input node of the control circuit 212s in a state where the switch 213 remains turned off.

The assist circuit 215j includes a capacitive element C2. The capacitive element C2 includes one end connected to the output node of the control circuit 212s and the other end connected to the power supply node VDD.

The assist circuit 215j includes, as illustrated in FIG. 11, the transistor NM32. The transistor NM32 is capacitively connected. The transistor NM32 may be an NMOS transistor.

In the transistor NM32, the source and the drain are commonly connected to the power supply node VDD, and the gate is connected to the output node OUT. This allows the transistor NM32 to function as the capacitive element C2.

For example, if the assist circuit 215j is omitted, at the time of power-on, the potential of the node N1 does not rise sufficiently and is near the L level, the transistor PM12 is half-on and the drain current flows in, easily charging the parasitic capacitance Cp in the line near the output node OUT, and the potential of the output node OUT can easily rise.

On the other hand, if the assist circuit 215j is provided, at the time of power-on, the potential of the node N1 does not rise sufficiently and is near the L level, the transistor PM12 is half-on and the drain current flows in, however, since the capacitive element C2 is also charged in addition to the parasitic capacitance Cp in the line, and the potential of the output node OUT is difficult to easily rise.

In other words, by providing the assist circuit 215j, the load capacitance in the vicinity of the output node OUT can be adjusted so that the potential of the output node OUT is lower at the time of power-on.

This can assist appearance of the L level at the output node of the control circuit 212s when the H level is input to the input node of the control circuit 212s in a state where the switch 213 remains turned off.

As described above, according to the third embodiment, in the PSW 21j of the semiconductor integrated circuit 1j, the assist circuit 214j may assist such that the H level appears at the output node of the control circuit 211s when the L level is input to the input node of the control circuit 211s in a state where the switch 213 remains turned off. This allows the leakage at the time of power-on to be suppressed in the switch 213 to be turned off, thereby being able to reduce power consumption in the standby state. Therefore, it is possible to appropriately interrupt the power supply to the connection destination of the PSW 21j.

In addition, according to the third embodiment, in the PSW 21j of the semiconductor integrated circuit 1j, the assist circuit 215j may assist such that the L level appears at the output node of the control circuit 212s when the H level is input to the input node of the control circuit 212s in a state where the switch 213 remains turned off. As a result, the signal to be transmitted to the PSW 21j in the next stage can be easily suppressed to the L level, and the leakage due to an influence of the preceding stage at the time of power-on can be suppressed in the switch 213 to be turned off, thereby being able to reduce power consumption in the standby state. Therefore, it is also possible to appropriately interrupt the power supply to the connection destination of the PSW 21j in the next stage.

Note that the PSW 21j′ may be configured such that the assist circuit 214j is omitted. In this case, in the PSW 21j′, the assist circuit 215j may assist such that the L level appears at the output node of the control circuit 212s when the H level is input to the input node of the control circuit 212s in a state where the switch 213 remains turned off. As a result, the signal to be transmitted to the PSW 21j in the next stage can be easily suppressed to the L level, and the leakage due to an influence of the preceding stage at the time of power-on can be suppressed in the switch 213 to be turned off.

Alternatively, the PSW 21j″ may be configured such that the assist circuit 215j is omitted. In this case, in the PSW 21j″, the assist circuit 214j assists such that the H level appears at the output node of the control circuit 211s when the L level is input to the input node of the control circuit 211s in a state where the switch 213 remains turned off. This allows the leakage at the time of power-on to be suppressed in the switch 213 to be turned off.

Alternatively, the assist circuit 214j may be realized in a layout configuration that adds coupling capacitance to the line between the control circuit 211s and the switch 213 with the other line instead of the capacitive element C1. For example, such a configuration can be realized by arranging the line between the control circuit 211s and the switch 213 parallel to the other line.

Alternatively, the assist circuit 215j may be realized in a layout configuration that adds coupling capacitance to the line between the control circuit 212s and the output node OUT with the other line instead of the capacitive element C2. For example, such a configuration can be realized by arranging the line between the control circuit 212s and the output node OUT parallel to the other line.

### Fourth Embodiment

Next, a semiconductor integrated circuit 1k according to the fourth embodiment will be explained. In the following, the parts that differ from the first embodiment to the third embodiment will be mainly explained.

While the first embodiment has been presented as an example of a configuration for adjusting with the threshold of the transistor so as to make the drive strength to the H level larger than the drive strength to the L level in the control circuit 211 and make the drive strength to the L level larger than the drive strength to the H level in the control circuit 212, the fourth embodiment is presented as an example of a configuration for adjusting with a ratio of the gate width to the gate length of the transistor.

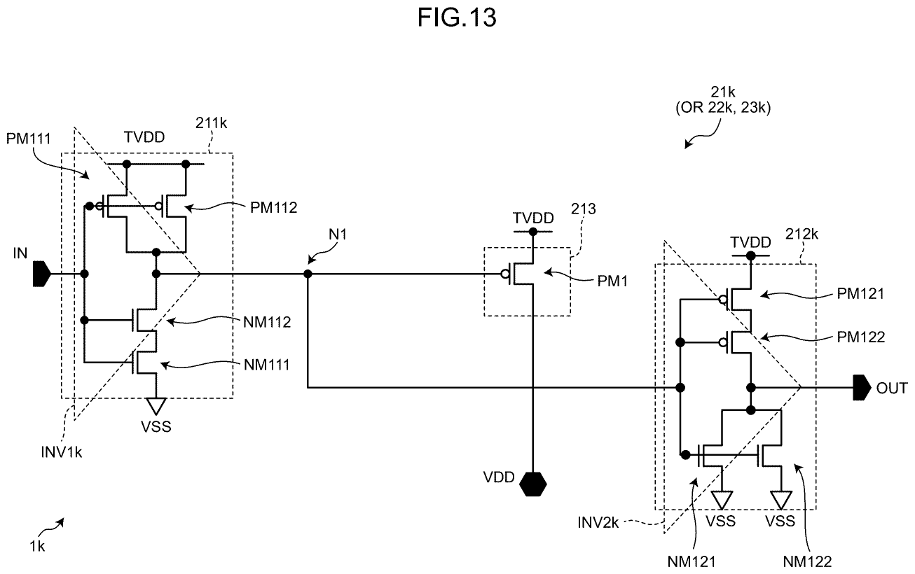

In the semiconductor integrated circuit 1k, a PSW 21k may be configured as illustrated in FIG. 13. FIG. 13 is a circuit diagram illustrating a detail configuration of the PSW 21k. In FIG. 13, the configuration of PSW 21k is illustrated as an example, and the configurations of PSW 22k and PSW 23k are similar to that of PSW 21k.

The inverter INV1k of the control circuit 211k is configured so that the ratio of the gate width to the gate length of a P-type transistor is greater than the ratio of the gate width to the gate length of an N-type transistor. The inverter INV1k may achieve such a configuration by making the ratio of the gate width to the gate length of one P-type transistor larger than the ratio of the gate width to the gate length of one N-type transistor. Alternatively, the inverter INV1k may achieve such a configuration by connecting multiple transistors in parallel on the power supply node TVDD side and connecting multiple transistors in series on the ground node VSS side.

The inverter INV1k includes a transistor PM111, a transistor PM112, a transistor NM111, and a transistor NM112.

The transistor PM111 and the transistor PM112 are connected in parallel between the power supply node TVDD and the output node of the inverter INV1k. The transistor NM111 and the transistor NM112 are connected in series between the output node of the inverter INV1k and the ground node VSS. The parallel connection of the transistor PM111 and the transistor PM112 and the series connection of the transistor NM111 and the transistor NM112 are inverter-connected.

The transistor PM111 and the transistor PM112 may each be a PMOS transistor. The transistor NM111 and the transistor NM112 may each be an NMOS transistor.

In the transistor PM111, the transistor PM112, the transistor NM111, and the transistor NM112, gates are commonly connected to be connected to the input node IN. In the transistor PM111, the transistor PM112, and the transistor NM112, drains are commonly connected to be connected to the node N1. In the transistor NM112, the source is connected to the transistor NM111. In the transistor NM111, the drain is connected to the transistor NM112. In the transistor PM111 and the transistor PM112, the sources are each connected to the power supply node TVDD. In the transistor NM111, the source is connected to the ground node VSS.

In the inverter INV1k, it is assumed that all transistors have the same size, and if their gate lengths are L and their gate widths are W, the ratio of the total gate width to the total gate length of the transistor PM111 and the transistor PM112 is 2×W/L, which is larger than the ratio of the total gate width to the total gate length of the transistor NM111 and the transistor NM112, W/(2×l). As a result, it is possible to make the drive strength to the H level larger than the drive strength to the L level in the control circuit 211k.

Note that in the inverter INV1k, the number of transistors connected in parallel on the power supply node TVDD side may be three or more, and the number of transistors connected in series on the ground node VSS side may be three or more.

The inverter INV2k of the control circuit 212k is configured so that the ratio of the gate width to the gate length of an N-type transistor is greater than the ratio of the gate width to the gate length of a P-type transistor. The inverter INV2k may achieve such a configuration by making the ratio of the gate width to the gate length of one N-type transistor larger than the ratio of the gate width to the gate length of one P-type transistor. Alternatively, the inverter INV2k may achieve such a configuration by connecting multiple transistors in series on the power supply node TVDD side and connecting multiple transistors in parallel on the ground node VSS side.

The inverter INV2k includes a transistor PM121, a transistor PM122, a transistor NM121, and a transistor NM122.

The transistor PM121 and the transistor PM122 are connected in series between the power supply node TVDD and the output node of the inverter INV2k. The transistor NM121 and the transistor NM122 are connected in parallel between the output node of the inverter INV2k and the ground node VSS. The series connection of the transistor PM121 and the transistor PM122 and the parallel connection of the transistor NM121 and the transistor NM122 are inverter-connected.

The transistor PM121 and the transistor PM122 may each be a PMOS transistor. The transistor NM121 and the transistor NM122 may each be an NMOS transistor.

In the transistor PM121, the transistor PM122, the transistor NM121, and the transistor NM122, gates are commonly connected to be connected to the node N1. In the transistor PM122, the transistor NM121, and the transistor NM122, drains are commonly connected to be connected to the output node OUT. In the transistor PM122, the source is connected to the transistor PM121. In the transistor PM121, the drain is connected to the transistor PM122. In the transistor NM121 and the transistor NM122, the sources are each connected to the ground node VSS. In the transistor PM121, the source is connected to the power supply node TVDD.

In the inverter INV2k, it is assumed that all transistors have the same size, and if their gate lengths are L and their gate widths are W, the ratio of the total gate width to the total gate length of the transistor NM121 and the transistor NM122 is 2×W/L, which is larger than the ratio of the total gate width to the total gate length of the transistor PM121 and the transistor PM122, W/(2×l). As a result, it is possible to make the drive strength to the L level larger than the drive strength to the H level in the control circuit 212k.

Note that in the inverter INV2k, the number of transistors connected in series on the power supply node TVDD side may be three or more, and the number of transistors connected in parallel on the ground node VSS side may be three or more.

In addition, operations of the PSW 21k (or PSW 22k, PSW 23k) are similar to those in the first embodiment.

As described above, according to the fourth embodiment, in the semiconductor integrated circuit 1k, the PSW 21k is configured such that the drive strength to the H level is greater than the drive strength to the L level in the control circuit 211k. This allows the leakage at the time of power-on to be suppressed in the switch 213 to be turned off, thereby being able to reduce power consumption in the standby state. Therefore, it is possible to appropriately interrupt the power supply to the connection destination of the PSW 21k.

In addition, according to the fourth embodiment, in the semiconductor integrated circuit 1k, the PSW 21k is configured such that the drive strength to the L level is greater than the drive strength to the H level in the control circuit 212k. As a result, the signal to be transmitted to the PSW 21k in the next stage can be easily suppressed to the L level, and the leakage due to an influence of the preceding stage at the time of power-on can be suppressed in the switch 213 to be turned off, thereby being able to reduce power consumption in the standby state. Therefore, it is also possible to appropriately interrupt the power supply to the connection destination of the PSW 21k in the next stage.

It should be noted that the PSW 21k′ may be configured such that the drive strength to the H level is greater than the drive strength to the L level in the control circuit 211k and the drive strength to the L level and the drive strength to the H level in the control circuit 212s are equal. In the PSW 21k′, in contrast to the inverter INV2k illustrated in FIG. 13, the transistor PM121 is omitted and the transistor NM121 is omitted, and the inverter INV2s of the control circuit 212s may be configured. In this case, since the drive strength to the H level is larger than the drive strength to the L level in the control circuit 211 of the PSW 21k′, the node N1 can be easily set to the H level at the time of power-on. This allows the leakage at the time of power-on to be suppressed in the switch 213 to be turned off.

Alternatively, the PSW 21k″ may be configured such that the drive strength to the H level is substantially equal to the drive strength to the L level in the control circuit 211s and the drive strength to the L level is greater than the drive strength to the H level in the control circuit 212k. In the PSW 21k″, in contrast to the inverter INV1k illustrated in FIG. 13, the transistor PM111 is omitted and the transistor NM111 is omitted, and the inverter INV1s of the control circuit 211s may be configured. In this case, since the drive strength to the L level is greater than the drive strength to the H level in the control circuit 212 of the PSW 21k″, the output node OUT can be easily set to the L level at the time of power-on. This allows the leakage due to the influence from the preceding stage at the time of power-on to be suppressed in the switch 213 to be turned off.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor integrated circuit comprising:
a switch connected between a first power supply node and a second power supply node that turns off when receiving a first level at a control terminal;
a first control circuit having an input node and an output node connected to a control terminal of the switch; and
a second control circuit having an output node and an input node connected to a control terminal of the switch, wherein
the semiconductor integrated circuit satisfies at least one of a condition that drive strength to the first level is greater than drive strength to a second level in the first control circuit and another condition that drive strength to the second level is greater than drive strength to the first level in the second control circuit.

2. The semiconductor integrated circuit according to claim 1, wherein
the semiconductor integrated circuit satisfies both a condition that drive strength to the first level is greater than drive strength to the second level in the first control circuit and another condition that drive strength to the second level is greater than drive strength to the first level in the second control circuit.

3. The semiconductor integrated circuit according to claim 1, wherein
the semiconductor integrated circuit satisfies a condition that drive strength to the first level is greater than drive strength to the second level in the first control circuit and does not satisfy another condition that drive strength to the second level is greater than drive strength to the first level in the second control circuit.

4. The semiconductor integrated circuit according to claim 1, wherein
the semiconductor integrated circuit does not satisfy a condition that drive strength to the first level is greater than drive strength to the second level in the first control circuit and satisfies another condition that drive strength to the second level is greater than drive strength to the first level in the second control circuit.

5. The semiconductor integrated circuit according to claim 1, wherein
the semiconductor integrated circuit satisfies a condition that drive strength to the first level is greater than drive strength to the second level in the first control circuit, and
the first control circuit includes
a first P-type transistor and a first N-type transistor inverter-connected, wherein threshold voltage of the first P-type transistor is lower than threshold voltage of the first N-type transistor.

6. The semiconductor integrated circuit according to claim 1, wherein
the semiconductor integrated circuit satisfies a condition that drive strength to the second level is greater than drive strength to the first level in the second control circuit, and
the second control circuit includes
a second P-type transistor and a second N-type transistor inverter-connected, wherein threshold voltage of the second N-type transistor is lower than threshold voltage of the second P-type transistor.

7. The semiconductor integrated circuit according to claim 1, wherein
the semiconductor integrated circuit satisfies a condition that drive strength to the first level is greater than drive strength to the second level in the first control circuit, and
the first control circuit includes
a plurality of first P-type transistors and a plurality of first N-type transistors inverter-connected, wherein the plurality of first P-type transistors is connected in parallel and the plurality of first N-type transistor is connected in series.

8. The semiconductor integrated circuit according to claim 1, wherein
the semiconductor integrated circuit satisfies a condition that drive strength to the second level is greater than drive strength to the first level in the second control circuit, and
the second control circuit includes
a plurality of second P-type transistors and a plurality of second N-type transistors inverter-connected, wherein the plurality of second N-type transistors is connected in parallel and the plurality of second P-type transistor is connected in series.

9. The semiconductor integrated circuit according to claim 5, wherein
a difference between center voltage in the threshold voltage distribution of the first P-type transistor and center voltage for the threshold voltage of the first N-type transistor is more than half the width of the threshold voltage distribution of the first P-type transistor.

10. The semiconductor integrated circuit according to claim 6, wherein
a difference between center voltage in the threshold voltage distribution of the second P-type transistor and center voltage for the threshold voltage of the second N-type transistor is more than half the width of the threshold voltage distribution of the second P-type transistor.

11. A semiconductor integrated circuit comprising:
a switch connected between a first power supply node and a second power supply node that turns off when receiving a first level at a control terminal;
a first control circuit having an input node and an output node connected to the control terminal of the switch; and
a second control circuit having an output node and an input node connected to the control terminal of the switch,
the semiconductor integrated circuit further comprising at least one of:
a first assist circuit that assists, when a second level logically inverted from a first level is input to an input node of the first control circuit in a state where the switch remains turned off, appearance of the first level in an output node of the first control circuit; and
a second assist circuit that assists, when the first level is input to an input node of the second control circuit in a state where the switch remains turned off, appearance of the second level in an output node of the second control circuit.

12. The semiconductor integrated circuit according to claim 11, wherein
the semiconductor integrated circuit includes both the first assist circuit and the second assist circuit.

13. The semiconductor integrated circuit according to claim 11, wherein
the semiconductor integrated circuit includes the first assist circuit and does not include the second assist circuit.

14. The semiconductor integrated circuit according to claim 11, wherein
the semiconductor integrated circuit does not include the first assist circuit and includes the second assist circuit.

15. The semiconductor integrated circuit according to claim 11, wherein
the semiconductor integrated circuit includes the first assist circuit, and
the first assist circuit includes
at least one of a third P-type transistor or a third N-type transistor in which a drain is commonly connected to a control terminal of the switch and a source is commonly connected to power supply potential, the third P-type transistor having a gate and a back gate each connected to power supply potential, and the third N-type transistor having a gate and a back gate each connected to a ground potential.

16. The semiconductor integrated circuit according to claim 11, wherein
the semiconductor integrated circuit includes the second assist circuit, and
the second assist circuit includes
at least one of a fourth P-type transistor or a fourth N-type transistor in which a drain is commonly connected to a control terminal of the switch and a source is commonly connected to ground potential, the fourth P-type transistor having a gate and a back gate each connected to power supply potential, and the fourth N-type transistor having a gate and a back gate each connected to ground potential.

17. The semiconductor integrated circuit according to claim 11, wherein
the semiconductor integrated circuit includes the first assist circuit, and
the first assist circuit includes
a first capacitive element having one end connected to a control terminal of the switch and an other end connected to the first power supply node.

18. The semiconductor integrated circuit according to claim 11, wherein
the semiconductor integrated circuit includes the second assist circuit, and
the second assist circuit includes
a second capacitive element having one end connected to an output node of the second control circuit and an other end connected to a ground potential.

19. The semiconductor integrated circuit according to claim 17, wherein
the first capacitive element includes
a fifth P-type transistor in which a gate is connected to the control terminal, and a drain and a source are connected to the first power supply node.

20. The semiconductor integrated circuit according to claim 18, wherein
the second capacitive element includes
a fifth N-type transistor in which a gate is connected to the control terminal, and a drain and a source are connected to a ground potential.
